(19) United States
(12) Patent Application Publication
(10) Pub. No.: US 2009/0215380 A1
(43) Pub. Date: Aug. 27, 2009

(54) Fan module for failure backup

(75) Inventor: Shu-Ju Lin, Taipei (TW)

Correspondence Address: RABIN & Berdo, PC, 1101 14TH STREET, NW, SUITE 500, WASHINGTON, DC, 20005, US

(73) Assignee: INVENTEC CORPORATION, Taipei (TW)

(21) Appl. No.: 12/081,811

(22) Filed: Apr. 22, 2008

(30) Foreign Application Priority Data
Feb. 27, 2008 (TW) 097203373

(51) Int. Cl. H05K 5/00

(52) U.S. Cl. 454/184

(57) ABSTRACT

A fan module for failure backup includes a flow guide structure and a first and a second fan disposed coaxially. The first and second fans are accommodated in the flow guide structure, and the flow guide structure has an air inlet and two vents respectively corresponding to the first and the second fan. The two vents respectively have a movable cover plate. The first and the second fan operate at a low speed in a normal state, such that the cover plate assumes an open state to provide a low speed air flow. When one of the fans fails to operate, the cover plate thereof assumes a closed state, and the other fan operates in a high speed to provide a high speed air flow, thereby achieving a purpose of failure backup.

### CROSS-REFERENCE TO RELATED APPLICATIONS

This non-provisional application claims priority under 35 U.S.C. §119(a) on Patent Application No(s). 097203373 filed in Taiwan, R.O.C. on Feb. 27, 2008, the entire contents of which are hereby incorporated by reference.

### BACKGROUND OF THE INVENTION

1. Field of Invention

The present invention relates to a fan module, and more particularly to a fan module for failure backup.

2. Related Art

A common electronic device has various circuit boards and electronic components. With the improvement of the process, the fabrication of integrated circuits (IC) increasingly becomes precise and complicated, and the power consumption is consequently increased. When the electronic device operates, chip, IC, and other electronic components on the circuit board inside the electronic device generate heat energy during operation, and thus temperature inside the electronic device rises. If the temperature in the electronic device exceeds an upper limit of the normal working temperature of the electronic components, the electronic components may fail or even be burned down, which causes the failure of the electronic device. Therefore, the electronic device are usually provided with heat dissipation holes and fans, for dissipating the heat energy generated by the electronic components inside the electronic device when operating to the outside through the heat dissipation holes by air convection generated by the fans.

In order to solve the heat dissipation problem of the electronic device, a fan structure of single fan or dual fans connected in parallel has been disclosed in the prior art. Or, as shown in FIG. 1, an improved structure of a backup fan 1 is disclosed in ROC patent publication No. M245513. A plurality of axial fans is installed in an accommodation housing, so as to solve the problem that the heat of the electronic device cannot be dissipated when the fan of the heat dissipation device adopting the single fan structure fails to operate.

However, although the improved structure of the backup fan disclosed in the prior art can provide a backup function when one of the fans fails to operate, the axial fan has a larger volume, and the air intake direction and the air outlet direction are in the same axis. Therefore, when the front fan fails to operate, the air volume and the flow field of the back fan are prone to be influenced by the fan blades of the front fan. In addition, in the conventional fan structure with the dual fans connected in parallel, the vent is not provided with the cover plate. When one of the fans fails to supply air, the outlet air of the other fan may be easily sent back to the air inlet from the vent of the failed fan. Thus, not only the flow field of the backup fan is affected, but also the effective air outlet volume is reduced. Therefore, the heat dissipation efficiency is greatly reduced and the temperature rises, which influences the operation of the electronic device.

### SUMMARY OF THE INVENTION

Accordingly, the present invention is directed to provide a fan module for failure backup, capable of solving the problems or the defects of the prior art.

The fan module for failure backup provided by the present invention includes a flow guide structure, a first fan, and a second fan. The flow guide structure is used to guide the air flow generated by the fan module to the vent. The flow guide structure has an accommodation space for accommodating the first fan and the second fan, and the flow guide structure has an air inlet having an air intake direction perpendicular to an air outlet direction and two vents respectively corresponding to the first fan and the second fan. The two vents respectively have a movable cover plate. The first fan has a hub, a plurality of fan blades, and a motor. The plurality of fan blades is disposed around the hub. The second fan has a hub, a plurality of fan blades, and a motor. The plurality of fan blades is disposed around the hub, and the second fan and the first fan are disposed coaxially. The first fan and the second fan operate at a low speed in a normal state, such that the cover plate assumes an open state to provide a low speed air flow. When one of the fans fails to operate, the cover plate assumes a closed state, and the other fan operates at a high speed to provide a high speed air flow, so as to achieve the purpose of failure backup.

The effect of the present invention includes that the fans having the two vents disposed not in the same axis are serially connected, and a cover plate is respectively disposed at the two vents. Thus, when one of the fans fails to operate, the cover plate of the vent is closed, so as to avoid the outlet air of the backup fan in normal operation flowing back into the flow guide structure from the vent of the failed fan. Therefore, the air volume and the flow field of the backup fan in normal operation will not be influenced, and the heat dissipation efficiency will not be lowered, thus achieving the purpose of effective backup.

### BRIEF DESCRIPTION OF THE DRAWINGS

The present invention will become more fully understood from the detailed description given herein below for illustration only, and thus are not limitative of the present invention, and wherein:

FIG. 1 shows a conventional backup fan;

FIG. 2A is a three-dimensional cross-sectional view of a fan module for failure backup according to a first embodiment of the present invention;.

FIG. 2B is a side view of the fan module for failure backup according to the first embodiment of the present invention;

FIG. 3A is a schematic view of an action of the fan module for failure backup of the present invention;

FIG. 3B is a schematic view of an action of the fan module for failure backup of the present invention;

FIG. 3C is a front view of the fan module for failure backup when applied to the electronic device according to the first embodiment of the present invention;

FIG. 3D is a side view of the fan module for failure backup when applied to the electronic device according to the first embodiment of the present invention;

FIG. 4A is a three-dimensional cross-sectional view of a fan module for failure backup according to a second embodiment of the present invention;

FIG. 4B is a side view of the fan module for failure backup according to the second embodiment of the present invention;

FIG. 5A is a three-dimensional view of a fan module for failure backup according to a third embodiment of the present invention;

FIG. 5B is a three-dimensional view of the fan module for failure backup according to the third embodiment of the present invention;

FIG. 6A is a three-dimensional view of a fan module for failure backup according to a fourth embodiment of the present invention; and

FIG. 6B is a three-dimensional view of a fan module for failure backup according to a fifth embodiment of the present invention.

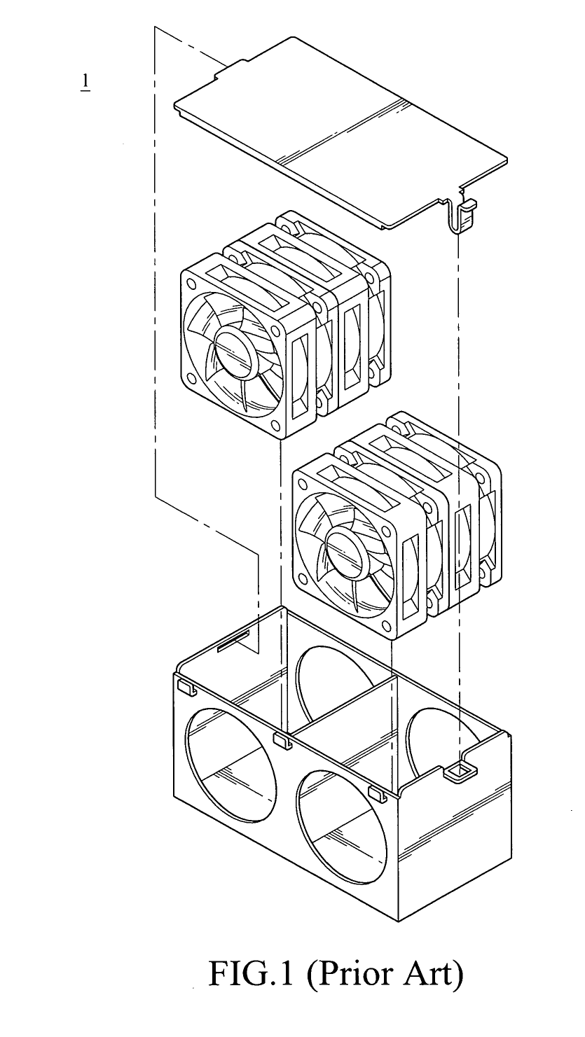

### DETAILED DESCRIPTION OF THE INVENTION

In order to make the objectives, structure, features, and functions of the present invention more apparent, the present invention is illustrated in the following embodiments.

The fan module for failure backup provided by the present invention is used to perform heat dissipation for a heat source in the electronic device, and is applicable to desktop computers, notebook computers, servers, and other electronic devices.

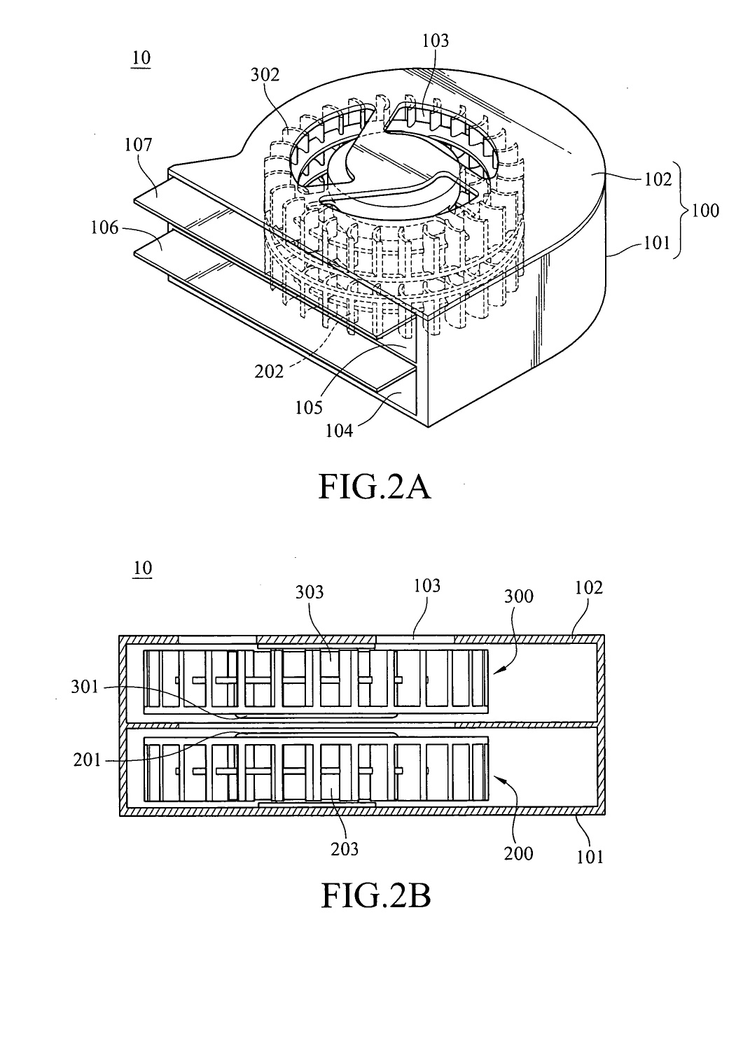

FIGS. 2A and 2B are a three-dimensional cross-sectional view and a side view of a fan module for failure backup according to a first embodiment of the present invention. As shown in the figures, the fan module 10 for failure backup provided by the present invention includes a flow guide structure 100, a first fan 200, and a second fan 300.

The flow guide structure 100 has an accommodation space formed by a base 101 and an upper lid 102. The first fan 200 and the second fan 300 may be accommodated in the accommodation space. The upper lid 102 may be closely joined with the base 101. The flow guide structure 100 is used to guide the air flow of the fan module, and the flow guide structure 100 has an air inlet 103 and two vents 104, 105. The air inlet 103 is located at the upper lid 102. An air intake direction of the air inlet 103 is perpendicular to an air outlet direction of the vents 104, 105, and the two vents 104, 105 respectively have movable cover plates 106, 107. The first fan 200 is a centrifugal fan fixed on the base 101 of the flow guide structure 100. The first fan 200 has a hub 201, a plurality of fan blades 202, and a motor 203. The plurality of fan blades 202 is disposed around the hub 201. The second fan 300 is a centrifugal fan fixed on the upper lid 102 of the flow guide structure 100. The second fan 300 has a hub 301, a plurality of fan blades 302, and a motor 303. The plurality of fan blades 302 is disposed around the hub 301. The second fan 300 and the first fan 200 are disposed coaxially.

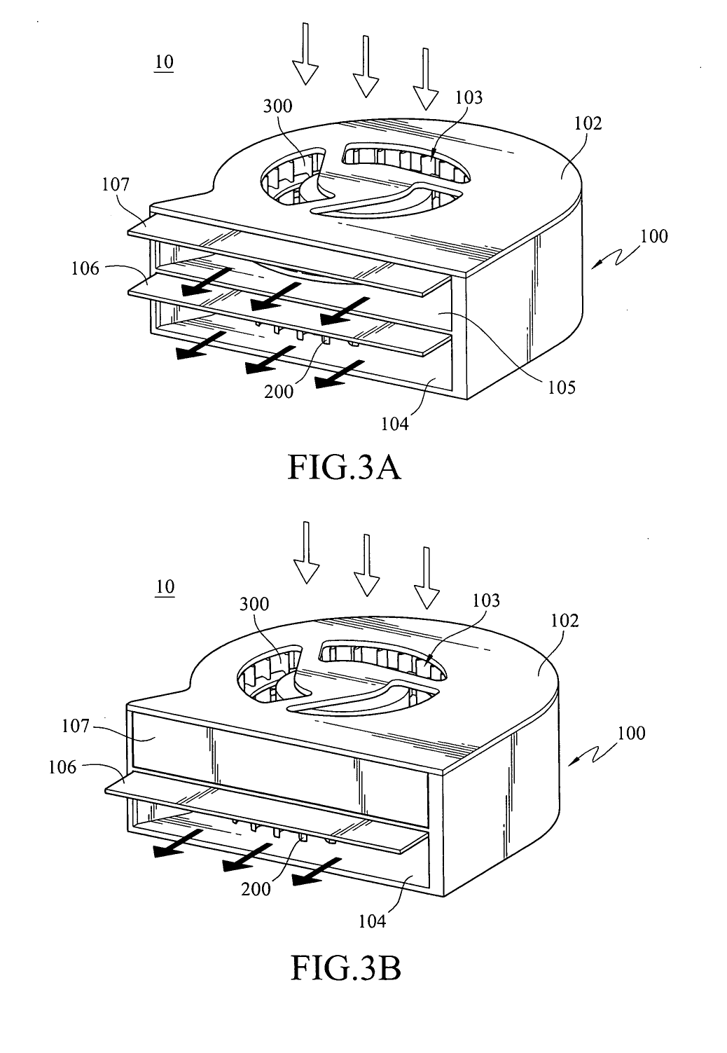

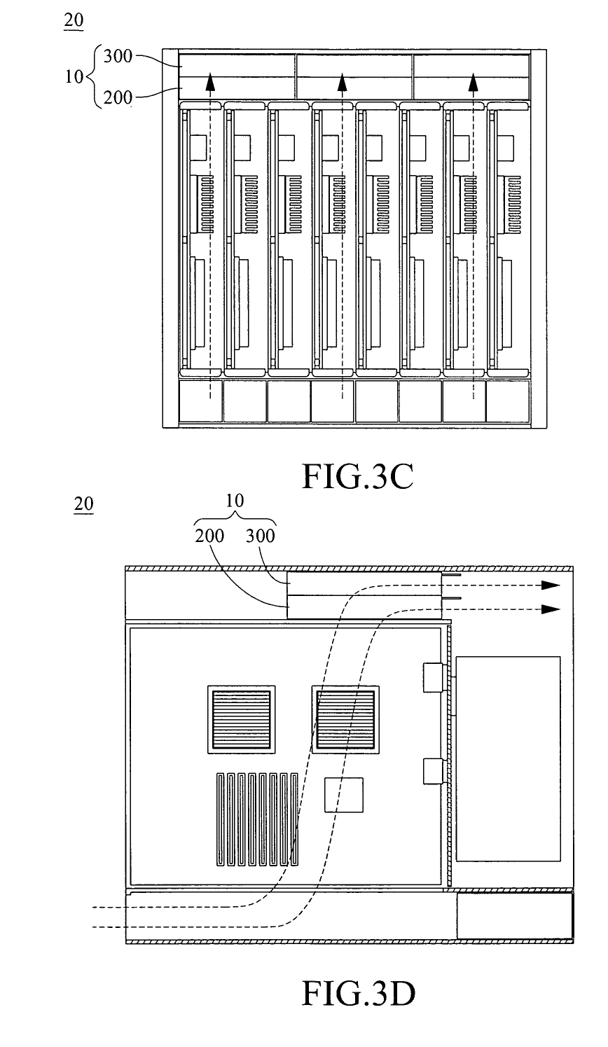

FIGS. 3A and 3B are schematic views of an action of the fan module for failure backup according to the first embodiment of the present invention. As shown in the figures, in the fan module 10 for failure backup provided by the present invention, a first fan 200 and a second fan 300 are accommodated in the flow guide structure 100. The flow guide structure 100 has an air inlet 103 located on the upper lid 102, and a first vent 104 and a second vent 105 respectively corresponding to the first fan 200 and the second fan 300. The first vent 104 and the second vent 105 respectively have a movable cover plate 106 and 107. In normal operation, the first fan 200 and the second fan 300 operate at a low speed at the same time, such that the cover plate 106 of the first vent 104 and the cover plate 107 of the second vent 105 are opened and respectively provide a low speed air flow. When the first fan 200 fails to operate, the first vent 104 is closed by the cover plate 106 of the first vent 104, the second fan 300 operates at a high speed, so as to provide a high speed air flow. Alternatively, when the second fan 300 fails to operate, the second vent 105 is closed by the cover plate 107 of the second vent 105, and the first fan 200 operates at a high speed, so as to provide a high speed air flow. The cover plates 106 and 107 are closed to avoid the intake air of the air inlet 103 from going out through the vent of the failed fan when one of the fans fails to operate, and also avoid the outlet air of the fan in operation from flowing back into the flow guide structure 100 through the vent of the failed fan to form a turbulent flow when one of the fans fails to operate.

FIGS. 3C and 3D are a front view and a side view of the fan module for failure backup when applied to the electronic device according to the first embodiment of the present invention. As shown in the figures, the fan module 10 for failure backup in which a first fan 200 and a second fan 300 are accommodated is disposed in the electronic device 20. When one of the fans in the fan module 10 fails to operate, the other fan can provide the outlet air in the same direction and will not be influenced by the fan blades of the failed fan, for dissipating heat of the electronic components in the air outlet direction.

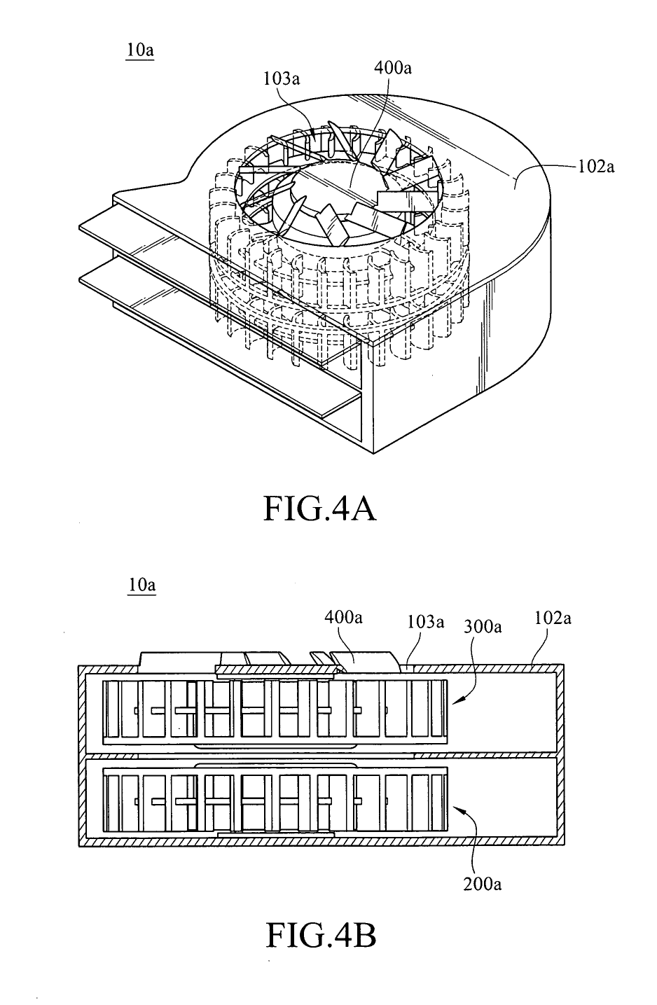

FIGS. 4A and 4B are a three-dimensional cross-sectional view and a side view of a fan module for failure backup according to a second embodiment of the present invention. As shown in the figures, different from the first embodiment, one flow guide fan 400a is additionally disposed on the air inlet 103a of the upper lid 102a of the fan module 10a for failure backup, so as to assist the intake of air. The guide fan 400a is fixed on the reversed side of the upper lid 102a facing the second fan 300a, and is disposed coaxially with the first fan 200a and the second fan 300a.

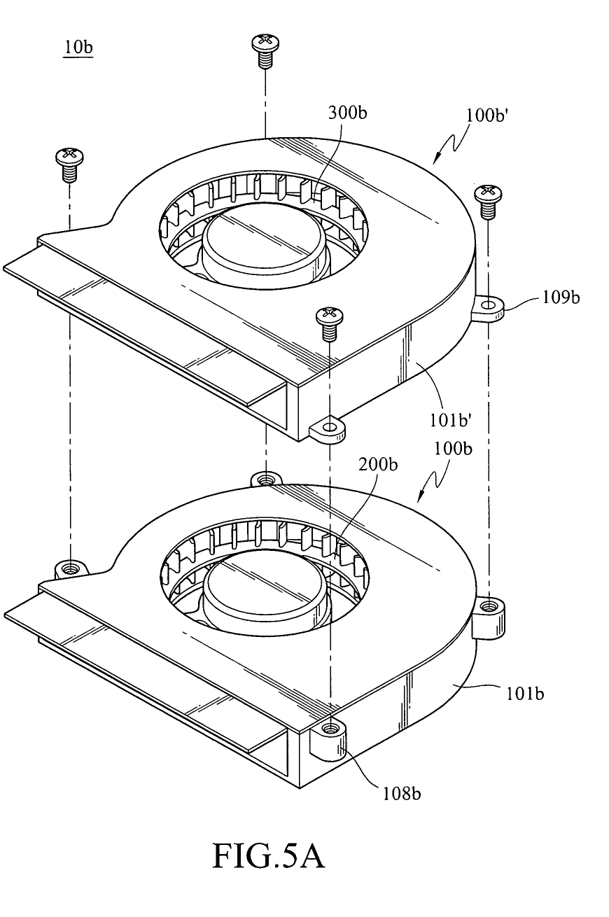

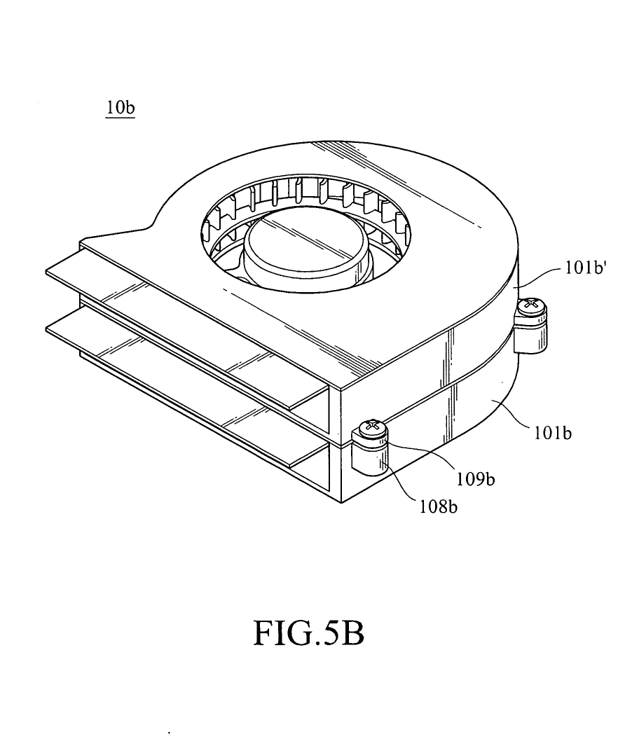

FIGS. 5A and 5B are three-dimensional views of a fan module for failure backup according to a third embodiment of the present invention. As shown in the figures, different from the first embodiment, the first fan 200b and the second fan 300b of the fan module 10b for failure backup respectively have a flow guide structure 100b, 100b′. The base 101b of the first fan 200b has a plurality of screw locking bases 108b on its outer side, and the base 101b′ of the second fan 300b has a plurality of screw penetrating portions 109b corresponding to the screw locking bases 108b of the first fan 200b on its outer side. The first fan 200b and the second fan 300b are connected together by means of screw locking.

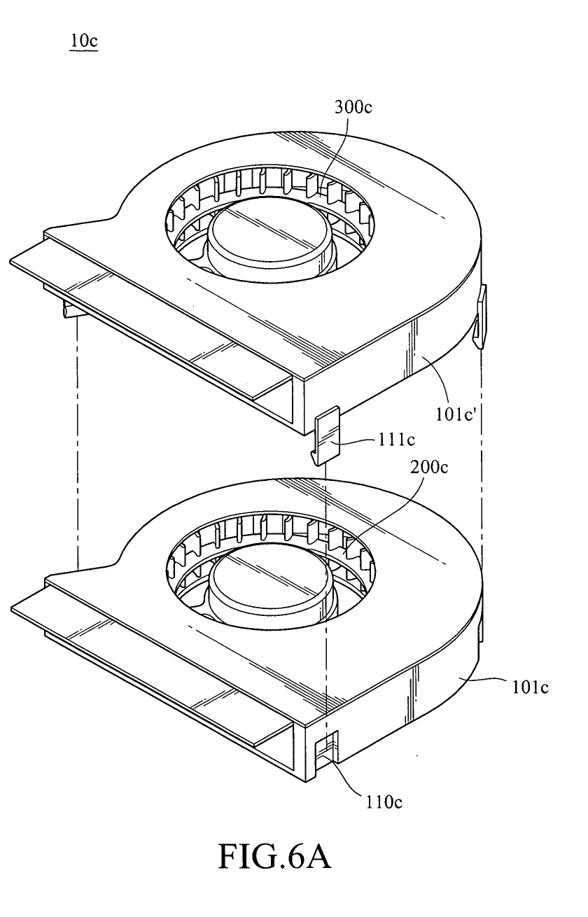

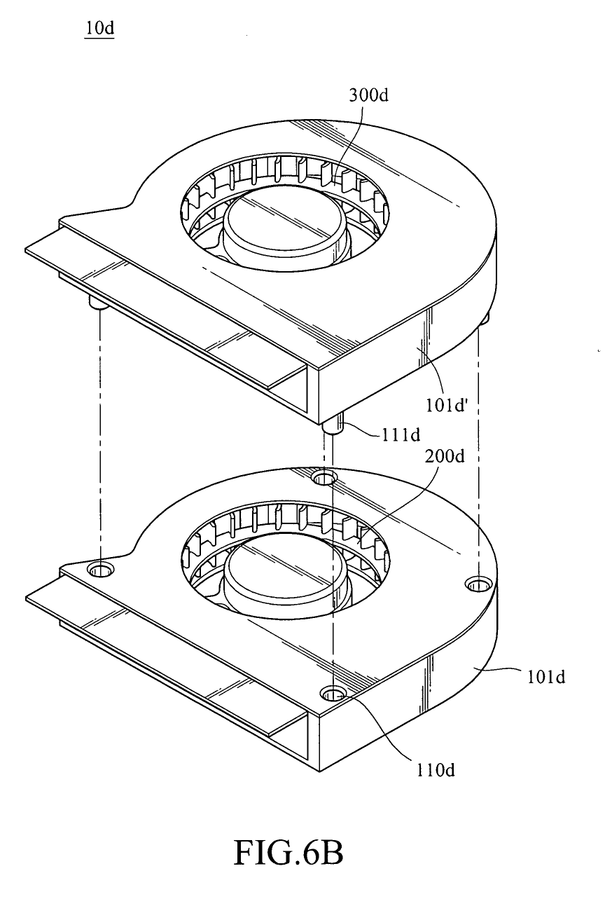

FIGS. 6A and 6B are three-dimensional views of a fan module for failure backup according to a fourth and a fifth embodiment of the present invention. As shown in the figures, the combination manner is different from that of the third embodiment. The bases 101c, 101d of the first fans 200c, 200d of the fan modules 10c, 10d for failure backup has a plurality of locking slots 110c, 110d on their outer side. The bases 101c′, 101d′ of the second fans 300c, 300d has a plurality of hooking parts 111c, 111d corresponding to the locking slots 110c, 110d of the first fans 200c and 200d. The first fans 200c, 200d and the second fans 300c, 300d are connected together by means of buckling.

What is claimed is:

1. A fan failure backup method, adapted to an electronic device, wherein:
a flow guide structure is disposed in an electronic device for accommodating a first fan and a second fan, the flow guide structure has an air inlet and a first vent and a second vent respectively corresponding to the first fan and the second fan, the first vent and the second vent respectively have a movable cover plate, and the first fan and the second fan operate at a low speed at the same time in a normal state, such that the cover plate is opened to provide a low speed air flow; when the first fan fails to operate, the first vent is closed by the cover plate of the first vent, and the second fan operates at a high speed, so as to provide a high speed air flow; alternatively, when the second fan fails to operate, the second vent is closed by the cover plate of the second vent, and the first fan operates at a high speed, so as to provide a high speed air flow.

2. The fan failure backup method as claimed in claim 1, wherein the fan is a centrifugal fan.

3. The fan failure backup method as claimed in claim 1, wherein an air intake direction of the air inlet is perpendicular to an air outlet direction of the vent.

4. A fan module for failure backup, comprising :
a flow guide structure, for guiding an air flow of the fan module, and having an accommodation space, wherein the flow guide structure has an air inlet and two vents;
a first fan, accommodated in the accommodation space, and having a hub, a plurality of fan blades, and a motor, wherein the plurality of fan blades is disposed around the hub; and
a second fan, accommodated in the accommodation space, and having a hub, a plurality of fan blades, and a motor, wherein the plurality of fan blades is disposed around the hub, and the second fan and the first fan are disposed coaxially.

5. The fan module for failure backup as claimed in claim 4, wherein an air intake direction of the air inlet is perpendicular to an air outlet direction of the vents.

6. The fan module for failure backup as claimed in claim 4, wherein the fan is a centrifugal fan.

7. The fan module for failure backup as claimed in claim 4, wherein the two vents respectively have a movable cover plate.

8. The fan module for failure backup as claimed in claim 4, wherein the flow guide structure has a base and an upper lid.

9. The fan module for failure backup as claimed in claim 8, wherein the first fan is fixed on the base of the flow guide structure.

10. The fan module for failure backup as claimed in claim 8, wherein the second fan is fixed on the upper lid of the flow guide structure.
